(19) United States
(12) Patent Application Publication
(10) Pub. No.: US 2002/0058428 A1
(43) Pub. Date: May 16, 2002

(54) CIRCUIT-BOARD CONNECTING TERMINAL

(76) Inventor: CHIEKO TORII, SHIZUOKA (JP)

Correspondence Address: SUGHRUE MION ZINN MACPEAK & SEAS PLLC, 2100 PENNSYLVANIA AVENUE NW, WASHINGTON, DC, 20037

(21) Appl. No.: 09/473,705

(22) Filed: Dec. 29, 1999

(30) Foreign Application Priority Data
Jan. 4, 1999 (JP) PHEI.11-000146

(51) Int. Cl. H05K 1/00

(52) U.S. Cl. 439/83

(57) ABSTRACT

The circuit-board connecting terminal (1) includes a small-width portion (7) to be inserted into a through hole (22) formed in a circuit board (12), a pair of taper portions (8) respectively to be abutted against an open end (23) of the through hole (22), and a large-width portion (5) formed so as to be continuous with the taper portions (8), while the small-width portion (7) can be connected to the inside of the through hole (22) by soldering. In the circuit-board connecting terminal (1), the taper portions (8) have a steep inclination angle, and are located at the open end (23) of the through hole (22), so as not to advance almost into the through hole (22).

### BACKGROUND OF THE INVENTION

1. Field of the Invention

The present invention relates to a circuit-board connecting terminal in which a lead portion thereof is inserted into a through hole formed in a circuit board and is soldered to the inside of the through hole to be thereby connected to the circuit board.

The present application is based on Japanese Patent Application No. Hei. 11-000146, which is incorporated herein by reference.

2. Description of the Related Art

Here, FIG. 4 shows a related circuit-board connecting terminal.

The related circuit-board connecting terminal 30 comprises a box-shaped electric contact portion 32 on one side of a base plate portion 31 thereof and a tab-shaped lead portion 33 on the other side of the base plate portion 31 thereof. The base plate portion 31 is formed so as to be continuous with the bottom portion of the electric contact portion 32. In the inside of the electric contact portion 32, there is disposed a contacting spring piece (not shown).

The leading end portion of the lead portion 33 is formed narrow in width (small width), while the present small-width portion 34 ranges through taper portions 35, which are respectively formed on opposite sides of the lead portion 33, with a large-diameter portion 36. Each of the taper portions 35 is formed rather long with a relatively gentle inclination angle θ₂. The large-width portion 36 is formed so as to be continuous with the base plate portion 31. The surface of the lead portion 33 including the small-width portion 34, taper portions 35 and large-width portion 36, and the surface of the base plate portion 31 face in the same direction.

In the above-mentioned circuit-board connecting terminal 30, the electric contact portion 32 is accommodated within a connector housing (not shown), and the lead portion 33 is inserted into a through hole 38 formed in a circuit board 37 as shown in FIG. 5. The leading end side of the small-diameter portion 34 extends through the through hole 38 and projects from the back surface 37a side of the circuit board 37, while the taper portions 35 are respectively abutted against the open end 40 of the through hole 38 on the surface 37b of the circuit board 37, thereby causing the circuit-board connecting terminal 30 to stop there.

Between the through hole 38 and lead portion 33, there is formed a clearance which can be filled with solder. The lead portion 33 is connected to a circuit (not shown) on the circuit board 37 by solder 39. The circuit is formed on the inner peripheral surface of the through hole 38 or on the surface 37b side of the circuit board 37. The solder 39 is supplied into the through hole 38 from the back surface 37a of the circuit board 37. As a method for supplying the solder 39, there are known a dip type soldering, a re-flow type soldering, and the like.

However, in the above-mentioned construction, since the taper portions 35 advance deeply into the through hole 38, the so called “wettability” of the solder 39 is poor and, therefore, in some cases, the solder 39 stops in the intermediate portion of the through hole 38 and therefore cannot reach the open end 40 of the through hole 38 (i.e., the mounting surface of a connector). In these cases, a circuit-board direct connecting connector (not shown) is disposed as an NG (no good) product, which incurs a wasteful cost.

Due to the above-mentioned poor rising of the solder 39, there is produced a clearance 41 between the taper portions 35 and solder 39 to thereby lower the value of an allowable current in conduction with the small-width portion 34. Moreover, due to an increase in the electric resistance of the small-width direction 34, the small-width portion 34 is heated to thereby raise a possibility that the heated small-width portion 34 can have an ill effect on the solder 39.

### SUMMARY OF THE INVENTION

It is therefore an object of the present invention to eliminate the above-mentioned drawbacks, and more specifically to provide a circuit-board connecting terminal which can surely raise solder up into a through hole formed in a circuit board to thereby eliminate the poor rising of the solder, can enhance the value of an allowable current in a lead portion thereof, and is able to prevent a small-width portion thereof from being heated.

To achieve the above object, according to an aspect of the present invention, there is provided a circuit-board connecting terminal which comprises a small-width portion inserted into and soldered to a through hole formed in a circuit board, a taper portion abutted against an open end of the through hole when the small-width portion is inserted into the through hole, and a large-width portion continuously formed with the taper portion, wherein the taper portion has a steep inclination angle for completely filling a clearance formed between an inner surface of the through hole and the small-width portion with a solder.

### BRIEF DESCRIPTION OF THE DRAWINGS

FIG. 1 is a plan view of a preferred embodiment of a circuit-board connecting terminal according to the present invention;

FIG. 2 is a longitudinal sectional view of an example of a circuit-board direct connecting connector using a circuit-board connecting terminal;

FIG. 3 is a longitudinal sectional view of the circuit-board connecting terminal according to the present invention and a circuit board, showing a state in which a lead portion of the circuit-board connecting terminal is connected to the circuit board by solder;

FIG. 4 is a plan view of a related circuit-board connecting terminal; and

FIG. 5 is a longitudinal section view of the related circuit-board connecting terminal and a circuit board, showing a state in which a lead portion of the related circuit-board connecting terminal is connected to the circuit board by solder.

### DETAILED DESCRIPTION OF THE PREFERRED EMBODIMENT

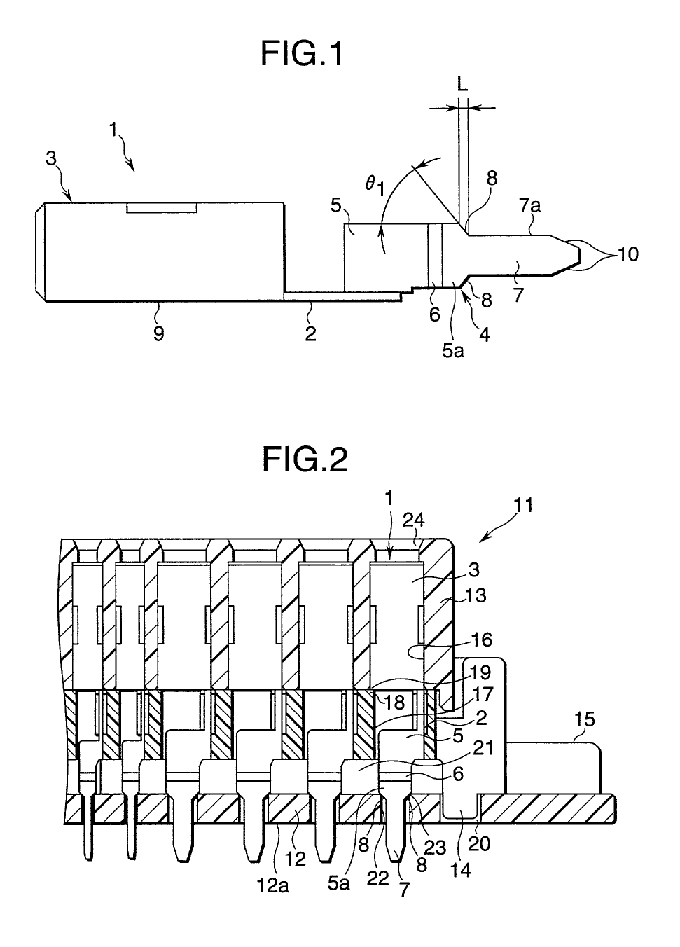

A circuit-board connecting terminal according to a preferred embodiment of the present invention will now be described with reference to FIGS. 1-3.

A circuit-board connecting terminal 1 comprises a box-shaped electric contact portion 3 on one side of a base plate portion 2 thereof and, on the other side of the base plate portion 2, a lead portion 4 which intersects at right angles to the base plate portion 2.

The lead portion 4 comprises a large-width portion 5 rising at right angles from one side of the base plate portion 2, a curved step portion 6 formed in the intermediate portion of the large-width portion 5 for absorbing the thermal distortion of the small-width portion 7, a pair of taper portions 8 and 8 respectively formed on the two sides of the leading end portion 5a of the large-width portion 5, and a small-width portion 7 formed so as to be continuous with the pair of taper portions 8 and 8 and extend on the same plane with the large-width portion 5.

Within the box-shaped electric contact portion 3, there is disposed a contacting spring piece (not shown). The base plate portion 2 serves also as a connecting portion between the electric contact portion 3 and lead portion 4. The base plate portion 2 is disposed not on the bottom surface portion of the electric contact portion 3 but on the side surface portion 9 thereof, so that, even if the width of the large-width portion 5 increases, the base plate portion 2 can prevent a pitch between the terminals from increasing. In other words, the width of the large-width portion 5 is set smaller than the transverse width of the electric contact portion 3 and the longitudinal width of the electric contact portion 3 (i.e., the width thereof in a direction crossing at right angles to the plane of the large-width portion 5) is set larger than the transverse width of the electric contact portion 3, whereby the allowable current value of the circuit-board connecting terminal 1 can be increased without increasing the transverse pitch of a circuit-board direct connecting connector 11. The width of the base plate portion 2 can be increased according to the longitudinal width of the electric contact portion 3.

Incidentally, the above-mentioned curved step portion 6 is not always indispensable. The curved step portion 6 is located near the small-width portion 7 so that it is able to easily absorb the thermal distortion of the small-width portion 7. The large-width portion 5, the leading end portion 5a thereof and curved step portion 6 are the same in the width. The length L of the respective taper portions 8 and 8 is set short, for example, of the order of 0.3 mm. The inclination angle θ₁ of the taper portions 8 and 8 is set steeper than that of related terminal. The taper portions 8 and 8 respectively cross linearly the two side surfaces 7a of the small-width portion 7. On the two sides of the leading end portion of the small-width portion 7, there are formed guide tapers 10 for easy insertion of the leading end portion of the small-width portion 7.

FIG. 2 shows a state in which the circuit-board direct connecting connector 11 using the circuit-board connecting terminal 1 is mounted on a circuit board 12.

The circuit-board direct connecting connector 11 comprises a connector housing 13 made of synthetic resin and the circuit-board connecting terminal 1 accommodated in the connector housing 13.

On the outside of the connector housing 13, there are disposed a boss portion 14 for positioning the connector 11 with respect to the circuit board 12, and a flange portion 15 for fixing the connector 11. Terminal accommodating chambers 16 and 17 are formed in the connector housing 13, and communicated with each other in the vertical direction. The terminal accommodating chambers 16 and 17 are respectively used to accommodate the electric contact portion 3, the base plate portion 2 and the large-width portion 5 of the circuit-board connecting terminal 1. The lower-side terminal accommodating chamber 17 is formed narrower than the upper-side terminal accommodating chamber 16, while the shoulder portion 19 of the electric contact portion 3 is secured by a shoulder portion 18. Incidentally, the connector housing 13 is constructed such that it can be divided to upper and lower sections.

The boss portion 14 can be engaged with a hole portion 20 formed in the circuit board 12, whereas the flange portion 15 can be fixed to equipment, a casing or the like (not shown) provided on the circuit board 12 by a bolt (not shown). For example, a female connector with a wire harness (not shown) can be connected to the circuit-board direct connecting connector 11. The male terminal (not shown) of the female connector can be inserted from an insertion opening 24 into the electric contact portion 3 of the circuit-board connecting terminal 1.

An empty chamber 21 is formed on the lower side of the terminal accommodating chamber 17, that is, between the terminal accommodating chamber 17 and the circuit board 12. The leading end portion 5a of the large-width portion 5, the curved step portion 6 and the small-width portion 7 are respectively located within the empty chamber 21, the two taper portions 8 and 8 are respectively abutted against an open end 23 of a through hole 22 formed in the circuit board 12, and the small-width portion 7 extends through the through hole 22 and projects from the back surface 12a side of the circuit board 12.

The taper portions 8 and 8, in their respective intermediate portions in the height direction thereof, are brought into contact with the open end 23 of the through hole 22. Since the taper portions 8 and 8 are formed in a steep inclination angle and further in short length, the advancing length of the taper portions 8 and 8 into the through hole 22 is very short, that is, such an extent that can be disregarded. Therefore, the width of the small-width portion 7 within the through hole 22 does not almost vary, and therefore, over the whole length of the through hole 22 between the inner peripheral surface and the two side surfaces 7a (FIG. 1) of the small-width portion 7, there is formed a slit-shaped uniform clearance (reference numeral 22 is also used to designate this) which extends in parallel to the through hole 22. Although the taper portions 8 and 8 are short, they can be surely brought into contact with the open end 23 of the through hole 22, which can ensure of the centripetal action of the small-width portion 7 with respect to the through hole 22.

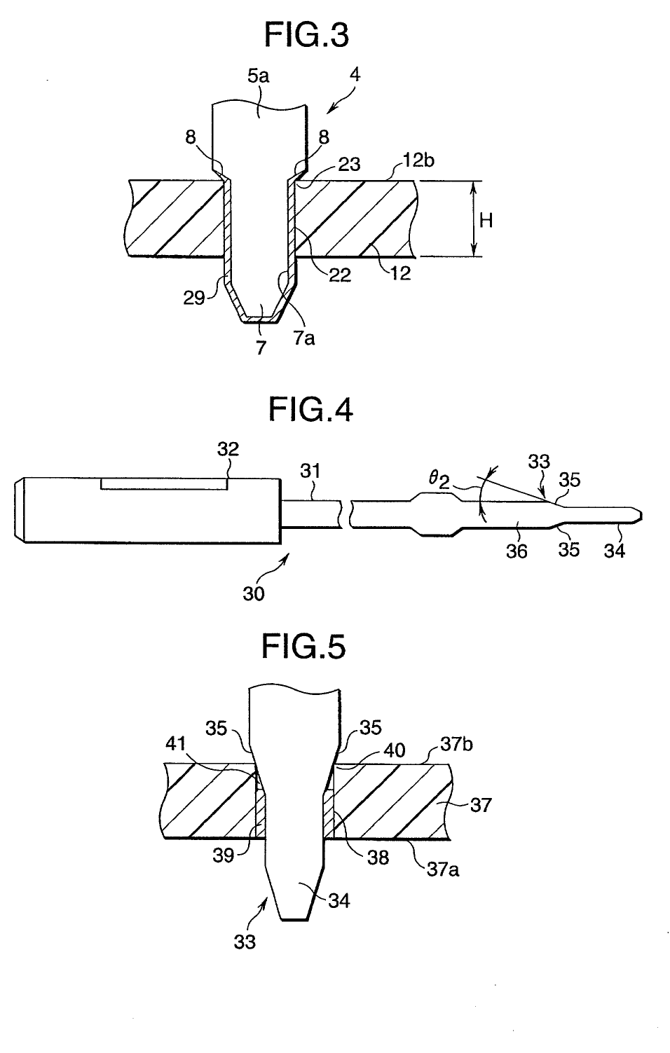

Formation of the slit-shaped uniform clearance (22) can enhance the wettability of solder 29. As shown in FIG. 3, the solder 29 is charged through the clearance (22) from the leading end side of the lead portion 4 (small-width portion 7) into the through hole 22 over the whole length H thereof. This can solve the problem that the solder can stop in the intermediate portion of the through hole 22 in the related terminal.

Thus, the solder 29 overflows along the taper portions 8 and 8 from the upper open end 23 onto the surface 12b (connector mounting surface) of the circuit board 12, thereby being able to positively connect and fix together a circuit (not shown) and the lead portion 4. The solder 29 adheres to the two side surfaces 7a of the small-width portion 7 and, in the taper portions 8 and 8, the width of the small-width portion 7 increases up to almost the same width (a width near the width of the large-width portion 5) of the leading end portion 5a of the large-width portion 5 (FIG. 1) to thereby increase the conductive section area of the small-width portion 7. Therefore, in the small-width portion 7 as well, there can be maintained almost the same allowable current value as in the leading end portion 5a of the large-width portion 5.

Accordingly, a larger current is allowed to flow in the small-width portion 7 when compared with the related circuit-board connecting terminal, and further, the heated small-width portion 7 caused by the increased electric resistance thereof can be prevented. If the same allowable current value as in the related circuit-board connecting terminal is necessary, then the small-width portion 7 can be made narrower (finer), which makes it possible to reduce the diameter of the through hole 22 in the circuit board 12. Therefore, if the arrangement of the circuit-board connecting terminal 1 is duly considered, then it is possible to realize a fine pitch in the lead portion 4.

As described above, according to the present invention, since the taper portions do not almost advance into the through hole, the clearance formed between the through hole and small-width portion can be filled with the solder over the whole length of the through hole. This can prevent the poor rising of the solder found in the related structure, makes it possible to positively connect together the circuit-board connecting terminal and circuit board, and can reduce the cost that is necessary for disposing the NG goods. Furthermore, due to the fact that the solder can adhere from the two side surfaces of the small-width portion to the taper portions to thereby increase the width of the small-width portion, the allowable current value can be increased in the small-width portion as well as the electric resistance of the small-width portion can be reduced, thereby making it difficult for the small-width portion to be heated, which can eliminate a possibility that the solder can be thermally influenced.

What is claimed is:

1. A circuit-board connecting terminal, comprising:
a small-width portion inserted into and soldered to a through hole formed in a circuit board;
a taper portion abutted against an open end of the through hole when the small-width portion is inserted into the through hole; and
a large-width portion continuously formed with the taper portion,
wherein the taper portion has a steep inclination angle for completely filling a clearance formed between an inner surface of the through hole and the small-width portion with a solder.
